(19) United States
(12) Patent Application Publication
(10) Pub. No.: US 2022/0077010 A1
(43) Pub. Date: Mar. 10, 2022

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takumi TAJIKA, Kanazawa Ishikawa (JP); Hiroshi OHTA, Nonoichi Ishikawa (JP); Shunsuke NITTA, Hakusan Ishikawa (JP)

(21) Appl. No.: 17/193,587

(22) Filed: Mar. 5, 2021

(30) Foreign Application Priority Data
Sep. 10, 2020 (JP) 2020-152200

(51) Int. Cl. H01L 23/02; H01L 23/31; H01L 23/29

(52) U.S. Cl. CPC H01L 23/02; H01L 23/293; H01L 23/31

(57) ABSTRACT

A semiconductor device includes a semiconductor element and resin. The semiconductor element includes a semiconductor part, first and second electrodes. The semiconductor part includes a back surface, a front surface at a side opposite to the back surface, and a side surface linking the back front surfaces. The semiconductor part includes a groove in the side surface. The groove surrounds the semiconductor part. The first electrode is provided on the back surface of the semiconductor part. The second electrode is provided on the front surface of the semiconductor part. The resin hermetically seals the semiconductor element. The resin includes a portion embedded in the groove.

### CROSS-REFERENCE TO RELATED APPLICATIONS

This application is based upon and claims the benefit of priority from Japanese Patent Application No. 2020-152200, filed on Sep. 10, 2020; the entire contents of which are incorporated herein by reference.

### FIELD

Embodiments relate to a semiconductor device.

### BACKGROUND

A semiconductor device includes a package in which a semiconductor chip is hermetically sealed by using a resin or the like. In such a semiconductor device, there are cases where the airtightness is degraded by external air penetrating via an interface between the resin and a terminal for connecting the semiconductor chip to an external circuit.

### BRIEF DESCRIPTION OF THE DRAWINGS

FIG. 1 is a schematic cross-sectional view showing a semiconductor device according to an embodiment;

FIGS. 2A to 4C are schematic cross-sectional views showing a method for manufacturing the semiconductor element according to the embodiment;

FIGS. 5A and 5B are schematic views showing the semiconductor element according to the embodiment; and

FIG. 6 is a schematic cross-sectional view showing the semiconductor element according to a modification of the embodiment.

### DETAILED DESCRIPTION

According to one embodiment, a semiconductor device includes a semiconductor element and resin. The semiconductor element includes a semiconductor part, a first electrode, and a second electrode. The semiconductor part includes a back surface, a front surface at a side opposite to the back surface, and a side surface linking the back surface and the front surface. The semiconductor part includes a groove in the side surface. The groove surrounds the semiconductor part. The first electrode is provided on the back surface of the semiconductor part. The second electrode is provided on the front surface of the semiconductor part. The resin hermetically seals the semiconductor element. The resin includes a portion embedded in the groove.

Embodiments will now be described with reference to the drawings. The same portions inside the drawings are marked with the same numerals; a detailed description is omitted as appropriate; and the different portions are described. The drawings are schematic and conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

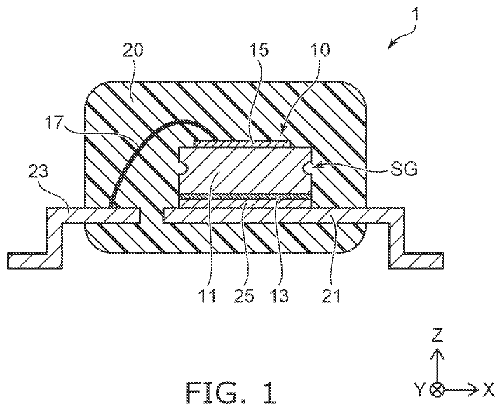

FIG. 1 is a schematic cross-sectional view showing a semiconductor device 1 according to an embodiment. The semiconductor device 1 includes a semiconductor element 10 and a resin 20. The resin 20 hermetically seals the semiconductor element 10. The semiconductor element 10 is, for example, a MOS (Metal Oxide Semiconductor) transistor. The embodiment is not limited to the following examples. The semiconductor element 10 may be a diode, an IGBT (Insulated Gate Bipolar Transistor), etc.

As shown in FIG. 1, the semiconductor element 10 includes a semiconductor part 11, a first electrode 13, and a second electrode 15. The first electrode 13 is provided on the back surface of the semiconductor part 11. The second electrode 15 is provided on the front surface of the semiconductor part 11. The semiconductor part 11 is, for example, silicon. The first electrode 13 and the second electrode 15 are, for example, metal layers including aluminum, etc.

The semiconductor part 11 includes a side surface that links the back surface and the front surface of the semiconductor part 11. The semiconductor part 11 includes a groove SG provided in the side surface. For example, the groove SG extends along the X-Y plane. For example, the groove SG is provided to surround the semiconductor part 11.

For example, the semiconductor element 10 is mounted on a lead 21. The lead 21 is, for example, a metal plate including copper. The semiconductor element 10 is mounted so that the first electrode 13 is toward the lead 21. For example, the semiconductor element 10 is electrically connected to the lead 21 via a solder material 25.

For example, the semiconductor element 10 is electrically connected to a lead 23 via a metal wire 17. The lead 23 is, for example, a metal plate including copper. The metal wire 17 is bonded to the second electrode 15 and the lead 23. The metal wire 17 is, for example, a gold wire.

The semiconductor element 10 is hermetically sealed using the resin 20. The resin 20 is, for example, an epoxy resin. The resin 20 is molded to cover the semiconductor element 10, the metal wire 17, and the leads 21 and 23. The lead 21 includes a mounting portion that is provided inside the resin 20, and a terminal that extends out from the resin 20. The lead 23 includes a bonding portion that is provided inside the resin 20 and is connected to the metal wire 17, and another terminal that extends out from the resin 20.

The groove SG in the side surface of the semiconductor part 11 is filled with resin 20. The resin 20 includes a portion provided in the groove SG. The adhesion strength between the semiconductor element 10 and the resin 20 can be increased thereby. Also, by providing the groove SG, the creepage distance can be increased between the second electrode 15 and outside the resin 20 along the interface of the resin 20 and the lead 21 and the interface of the resin 20 and the semiconductor part 11. The external air penetrating into the active region of the semiconductor element 10 can be suppressed thereby.

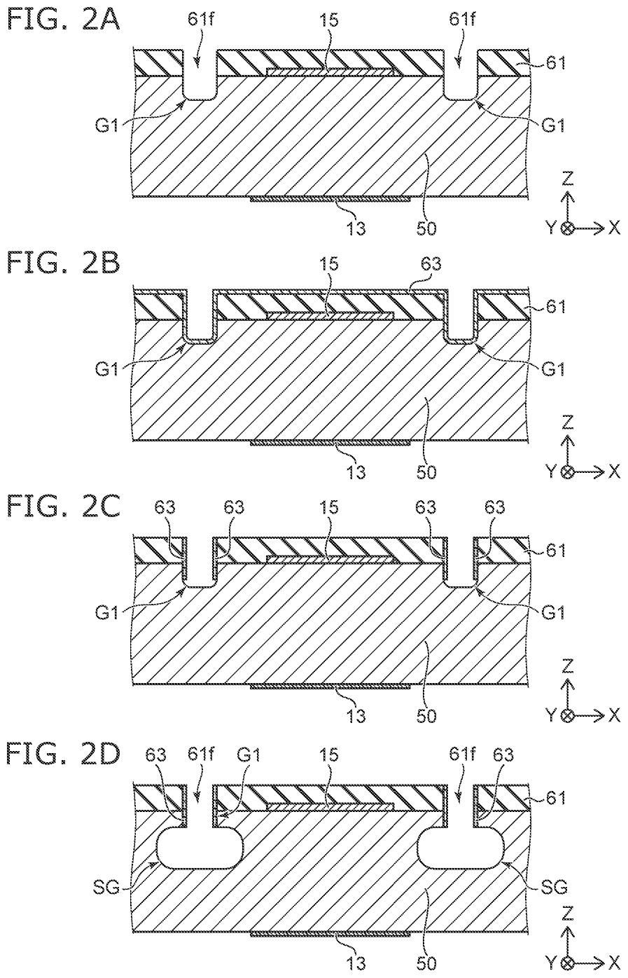

A method for manufacturing the semiconductor element 10 according to the embodiment will now be described with reference to FIGS. 2A to 4C. FIGS. 2A to 4C are schematic cross-sectional views illustrating a dicing process of the semiconductor element 10.

As shown in FIG. 2A, a groove G1 is formed by using an etching mask 61 formed on the front surface of a semiconductor wafer 50. The semiconductor wafer 50 is, for example, a silicon wafer. The first electrode 13 is formed on the back surface of the semiconductor wafer 50. The second electrode 15 is formed on the front surface of the semiconductor wafer 50. For example, a MOS structure (not-illustrated) is provided between the semiconductor wafer 50 and the second electrode 15.

The etching mask 61 is formed to cover the second electrode 15. The etching mask 61 is, for example, a resist film. The etching mask 61 has an opening 61f. The opening 61f is formed, for example, along the dicing line of the semiconductor wafer 50.

The groove G1 is formed by, for example, anisotropic dry etching using sulfur hexafluoride (SF₆) as an etching gas. The groove G1 is formed by selectively removing the semiconductor wafer 50 to a prescribed depth using the etching mask 61.

As shown in FIG. 2B, a protective film 63 that covers the inner surface of the groove G1 is formed. The protective film 63 is, for example, a carbon film. For example, the protective film 63 is deposited by plasma CVD (Chemical Vapor Deposition) in which a Teflon (registered trademark)-based gas such as C₄F₈ or the like is used as a raw material. The protective film 63 also covers the etching mask 61.

As shown in FIG. 2C, the portion of the protective film 63 that covers the bottom surface of the groove G1 is selectively removed. For example, the protective film 63 is removed by anisotropic dry etching so that the portion that is deposited on the inner wall of the groove G1 remains. In other words, the portion of the protective film 63 that is deposited on the upper surface of the etching mask 61 also is removed.

As shown in FIG. 2D, the groove SG is formed in the semiconductor wafer 50. The groove SG is formed by selectively removing the semiconductor wafer 50 via the groove G1 and the opening 61f of the etching mask 61. For example, the groove SG is formed using isotropic dry etching. Because the inner wall of the groove G1 is covered with the protective film 63, the etching proceeds from the bottom surface of the groove G1; and a cavity that spreads in the lateral direction is formed by side etching. For a constant isotropic dry etching rate, the etching time of the groove SG is greater than the etching time of the groove G1.

For example, it is favorable to stop the etching for forming the groove SG before the protective film 63 is consumed by the isotropic dry etching. To increase the lateral width of the groove SG, for example, the protective film 63 is formed to be thick, and the etching time is increased.

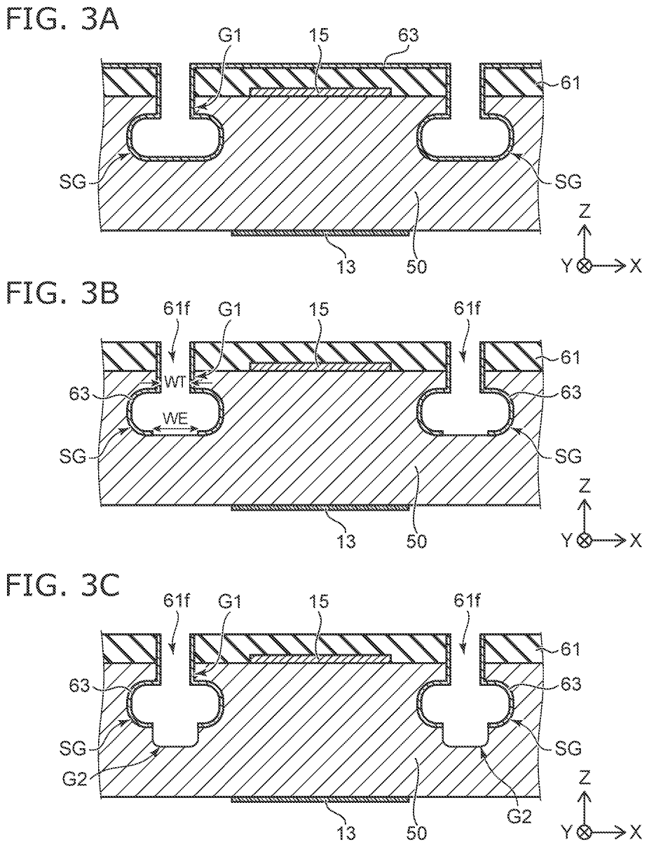

As shown in FIG. 3A, the protective film 63 is re-formed to cover the inner surface of the groove SG. The protective film 63 also covers the etching mask 61 and the inner wall of the groove G1.

As shown in FIG. 3B, the portion of the protective film 63 that is deposited at the bottom surface of the groove SG is selectively removed by, for example, anisotropic dry etching. The protective film 63 is selectively removed via the groove G1 and the opening 61f of the etching mask 61. The protective film 63 is selectively removed so that the portion that is deposited on the inner wall of the groove G1 and the inner wall of the groove SG remains. A width WE of the region of the bottom surface of the groove SG where the protective film 63 is removed is, for example, equal to or greater than a width WT in the X-direction of the groove G1.

As shown in FIG. 3C, a groove G2 is formed below the groove SG. The groove G2 is formed by selectively removing the semiconductor wafer 50 via the portion of the bottom surface of the groove SG where the protective film 63 was selectively removed. For example, the groove G2 is formed by anisotropic dry etching. For a constant isotropic dry etching rate, the etching time of the groove G2 is less than the etching time of the groove SG. The etching time of the groove G2 is set to be equal to or greater than the etching time of the groove G1.

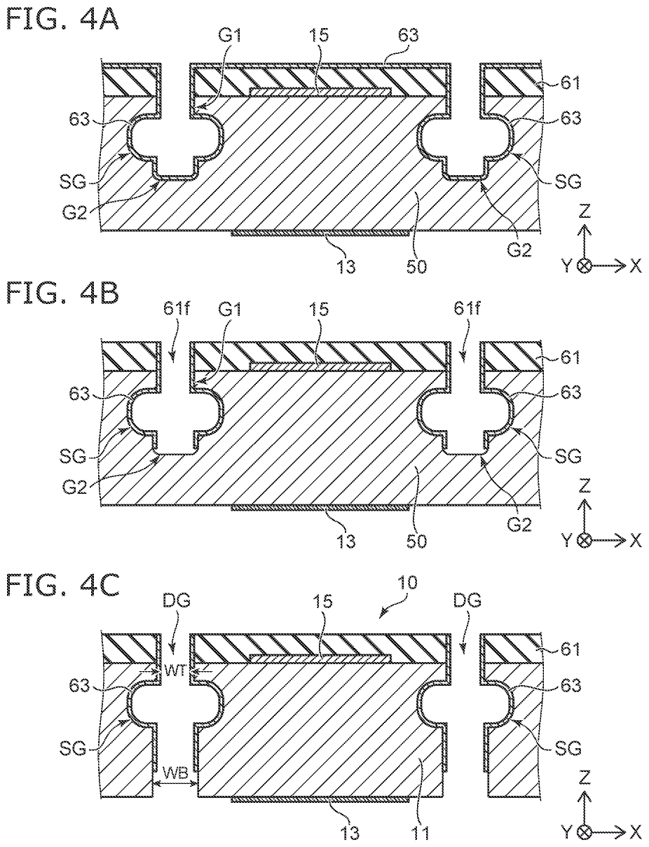

As shown in FIG. 4A, the protective film 63 is re-formed to cover the inner surface of the groove G2. The protective film 63 also covers the etching mask 61, the inner wall of the groove SG, and the inner wall of the groove G1.

As shown in FIG. 4B, the portion of the protective film 63 that is deposited on the bottom surface of the groove G2 is selectively removed by, for example, anisotropic dry etching. The protective film 63 is selectively removed via the groove G2, the groove G1, and the opening 61f of the etching mask 61.

Continuing, a dividing groove DG that communicates from the front surface to the back surface of the semiconductor wafer 50 is formed by repeating the selective removal of the semiconductor wafer 50, the formation of the protective film 63, and the selective removal of the protective film 63. Thereby, the semiconductor wafer 50 is divided into the multiple semiconductor parts 11; and the semiconductor element 10 is made into chips as shown in FIG. 4C. Finally, the etching mask 61 and the protective film 63 are removed by, for example, oxygen ashing.

As shown in FIG. 4C, a width WB of the region of the dividing groove DG that is lower than the groove SG is formed to be greater than the width WT of the region that is higher than the groove SG. In other words, the semiconductor part 11 is formed to have a configuration in which the portion that is positioned higher than the groove SG protrudes outward of the portion that is positioned lower than the groove SG. The adhesion strength between the semiconductor element 10 and the resin 20 can be further improved thereby.

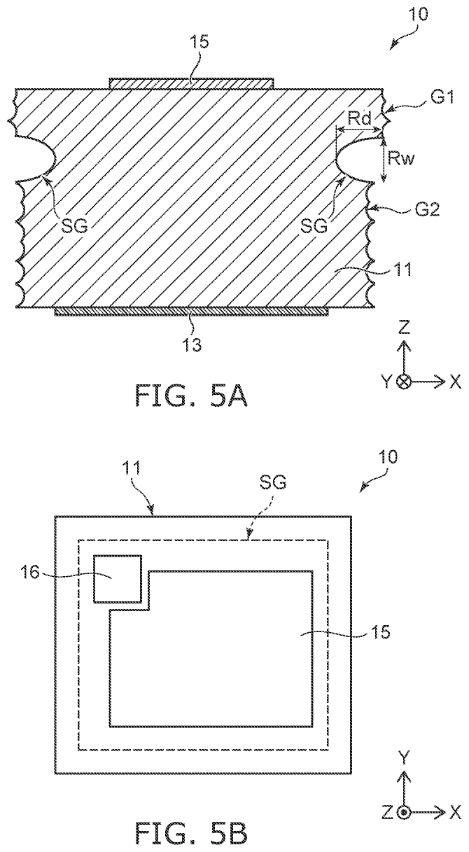

FIGS. 5A and 5B are schematic views showing the semiconductor element 10 according to the embodiment. FIG. 5A is a cross-sectional view of the semiconductor element 10. FIG. 5B is a plan view illustrating the front surface of the semiconductor element 10.

FIG. 5A illustrates a cross section of the semiconductor element 10 formed by the chip singulation technique described above. As shown in FIG. 5A, the semiconductor part 11 includes recesses that correspond to the groove SG and the grooves G1 and G2. A depth Rd in the X-direction of the groove SG is greater than the depths in the X-direction of the recesses. The depth Rd of the groove SG is not less than 2 times the maximum depth of the recesses. A width Rw in the Z-direction of the groove SG is greater than the widths in the Z-direction of the recesses.

Although one process of forming the groove G1 is shown in the example shown in FIGS. 2A to 2C, the process is not limited thereto. For example, a groove G1 that is deeper in the Z-direction may be formed by repeating the selective etching of the semiconductor wafer 50, the formation of the protective film 63, and the selective removal of the protective film 63.

As shown in FIG. 5B, the semiconductor element 10 further includes a control electrode 16 in addition to the second electrode 15. In the example, the first electrode 13 (referring to FIG. 5A) is a drain electrode, and the second electrode 15 is a source electrode. The control electrode 16 is, for example, a gate electrode that is linked to the gate of the MOS structure. For example, the groove SG is provided along the outer edge of the semiconductor part 11 to surround the semiconductor part 11. The depth of the groove SG along the front surface of the semiconductor part 11 is shallower than the distance between the second electrode 15 and the outer edge of the front surface of the semiconductor part 11. Also, the depth of the groove SG along the front surface of the semiconductor part 11 is shallower than the distance between the control electrode 16 and the outer edge of the front surface of the semiconductor part 11.

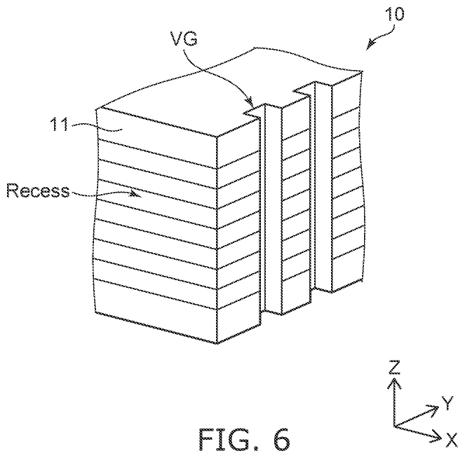

FIG. 6 is a schematic cross-sectional view showing the semiconductor element 10 according to a modification of the embodiment. In the example, the semiconductor part 11 includes a groove VG extending in the Z-direction. The groove VG is provided in the side surface of the semiconductor part 11 and extends from the front surface to the back surface of the semiconductor part 11. The first electrode 13 is located on the back surface of the semiconductor part 11; and the second electrode 15 is located on the front surface of the semiconductor part 11 (referring to FIG. 5A).

For example, the groove VG is formed by providing a recess portion that is recessed partially inward in the opening 61f of the etching mask 61 (referring to FIG. 2A). Multiple grooves VG are formed in the side surface of the semiconductor part 11.

As shown in FIG. 6, the groove VG may be provided in one side surface of the semiconductor part 11 or may be provided in each of the four side surfaces of the semiconductor part 11 (referring to FIG. 5B). At least two grooves VG may be provided in one side surface. By filling the resin 20 into the groove VG, the adhesion between the semiconductor element 10 and the resin 20 can be improved for the stress generated in the X-direction or the Y-direction.

The semiconductor element 10 includes a plurality of recesses that are provided in the side surface of the semiconductor part 11, and each extend in a direction along the front surface of the semiconductor part 11. The groove VG extends in direction crossing the recesses. The recesses each surround the semiconductor part 11. The recesses are arranged in the direction from the back surface toward the front surface of the semiconductor part 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a semiconductor element including a semiconductor part, a first electrode, and a second electrode,
the semiconductor part including a back surface, a front surface at a side opposite to the back surface, and a side surface linking the back surface and the front surface,
the semiconductor part including a groove in the side surface, the groove surrounding the semiconductor part,
the first electrode being provided on the back surface of the semiconductor part,
the second electrode being provided on the front surface of the semiconductor part; and
a resin hermetically sealing the semiconductor element, the resin including a portion embedded in the groove.

2. The device according to claim 1, further comprising:
a base connected via the first electrode to the semiconductor part at the back surface side,
the resin covering the semiconductor element on the base,
the semiconductor part including a first portion and a second portion,
the first portion being positioned at a higher level than a level of the groove,
the second portion being positioned at a lower level than the level of the groove,
the second portion being provided between the base and the first portion,
the first portion protruding further into the resin than the second portion in a direction parallel to the front surface of the semiconductor part.

3. The device according to claim 2, wherein
the base includes a mounting portion and a terminal, the mounting portion being sealed inside the resin and electrically connected to the semiconductor element, the terminal extending outward from the resin.

4. The device according to claim 1, wherein
the semiconductor part includes a plurality of recesses in the side surface, and
the groove has a depth in a first direction perpendicular to the side surface, the depth of the groove being not less than 2 times a maximum depth of the plurality of recesses in the first direction.

5. The device according to claim 1, wherein
the groove has a depth in a first direction perpendicular to the side surface, the depth of the groove being larger than a distance between the second electrode and an outer edge of the front surface of the semiconductor part.

6. The device according to claim 1, wherein
the semiconductor element further includes a third electrode apart from the second electrode on the front surface of the semiconductor part, and
the groove has a depth in a first direction perpendicular to the side surface, the depth of the groove being larger than a distance between the third electrode and an outer edge of the front surface of the semiconductor part.

7. The device according to claim 1, wherein
the first electrode is provided further inward than an outer edge of the back surface of the semiconductor part.

8. A semiconductor device, comprising:
a semiconductor element including a semiconductor part, a first electrode, and a second electrode,
the semiconductor part including a back surface, a front surface at a side opposite to the back surface, and a side surface linking the back surface and the front surface,
the semiconductor part including a groove in the side surface, the groove extending in a direction from the back surface toward the front surface and being linked to the front surface and the back surface,
the first electrode being provided on the back surface of the semiconductor part,
the second electrode being provided on the front surface of the semiconductor part; and
a resin hermetically sealing the semiconductor element and including a portion filled into the groove.

9. The device according to claim 8, wherein
the semiconductor part includes four of the side surfaces, and
at least two of the grooves are provided in one side surface of the four side surfaces.

10. The device according to claim 8, wherein
the semiconductor element includes a plurality of recesses provided on the side surface, the groove extending in a direction crossing the plurality of recesses.
